(19) United States
(12) Patent Application Publication
(10) Pub. No.: US 2026/0171757 A1
(43) Pub. Date: Jun. 18, 2026

(54) METHOD OF MANUFACTURING AN ELECTRONIC DEVICE

(71) Applicant: Commissariat à l'Energie Atomique et aux Energies Alternatives, Paris (FR)

(72) Inventors: Sophie BARBET, Grenoble cedex 09 (FR); Romain THIBON, Grenoble cedex 09 (FR)

(73) Assignee: Commissariat à l'Energie Atomique et aux Energies Alternatives, Paris (FR)

(21) Appl. No.: 19/423,624

(22) Filed: Dec. 17, 2025

(30) Foreign Application Priority Data
Dec. 18, 2024 (FR) FR2414543

(51) Int. Cl. H01S 5/223

(52) U.S. Cl. CPC H01S 5/223

(57) ABSTRACT

The manufacturing method makes it possible to manufacture an electronic device including a substrate; an electronic component formed from the substrate; a planarization layer made of resin and arranged on the electronic component; an electrically conductive element passing through the planarization layer, said electrically conductive element being in contact with a part of the electronic component and having a contact surface arranged on the side of a face of the planarization layer opposite the substrate.

### TECHNICAL FIELD OF THE INVENTION

The technical field of the invention concerns electronics, and more particularly microelectronics. The invention relates to a method for manufacturing an electronic device comprising an electronic component and a planarization layer, notably formed in contact with the electronic component. The electronic component is preferentially a laser.

### STATE OF THE PRIOR ART

In the field of microelectronics, it is known to form an electronic component on a substrate in order to form an electronic device such as a chip, also called an electronic chip. Once the electronic component is complete, some electronic device structures require providing within the electronic device a planarization layer that at least in part covers the electronic component. The purpose of this planarization layer is to ensure that the topography of the electronic component does not constitute an impediment to the recovery of local contact, or to allow two chips to be connected together, for example, by transferring one onto the other, also known as “flip-chip”.

Thus, conventionally, the planarization layer can be opened locally up to the electronic component in order to form, from a through hole resulting from this opening, a via (also called a metallized hole) electrically connecting the electronic component so that the via has a contact surface on the side of the planarization layer opposite the substrate.

To this end, after depositing the planarization layer, it is common to form, on this planarization layer, a photosensitive resin layer, and then to expose the latter before carrying out a development that makes accessible one or several portions of the face of the planarization layer opposite to the substrate. Next, the planarization layer is dry-etched locally at portions with the dry etch selectively stopping on the electronic component. After the dry etch, the remainder of the photosensitive resin layer is removed so as to allow a metal deposition to be implemented at the locations where the planarization layer has been etched to allow a contact recovery (via formation) on the electronic component such that the deposited metal is accessible from the side of the face of the planarization layer opposite the substrate.

All these steps have a cost during the manufacture of the electronic device, this cost being increased when the etchings have to stop on materials different from the electronic component and/or at different levels above the substrate.

As an example, a conventional method for manufacturing an electronic device is given, the electronic component of which is a laser on a silicon substrate.

The manufacturing method comprises a step of forming the laser comprising an N-doped InP base arranged on the substrate and locally topped by a quantum layer intended to form a Fabry-Perot cavity of the laser. This quantum layer is topped by a P-doped InP layer intended to form a part of the laser. The laser formation step comprises the formation of first metallic connection terminals on the base, arranged at the same level above the substrate, and the formation of a second metallic connection terminal on the P-doped InP layer. The composition of the first metallic connection terminals notably differs, in terms of materials, from the composition of the second metallic terminal. It results that, in addition to using different compositions to form the first connection terminals and the second connection terminal, the first connection terminals are arranged at a first level above the substrate lower than a second level above the substrate where the second connection terminal is arranged.

Following the laser formation step, a planarization layer is formed on the substrate and the laser, this planarization layer comprising Benzo-Cyclo-Butene (also known by the abbreviation BCB).

On this planarization layer, the recovery of the first connection terminals and of the second connection terminal is done in two stages.

In a first stage, a positive photosensitive resin is deposited, which is exposed, and then developed to form a first etch mask in order to form an access to the first connection terminals through the planarization layer. Once the first etch mask has been formed, an inductively coupled plasma dry etching of the planarization layer is carried out, with stopping on the metal of the first connection terminals. Thereafter, the photosensitive resin is removed.

In a second stage, a positive photosensitive resin is deposited again, notably filling the access to the first connection terminals previously formed, which is exposed, and then developed to form a second etch mask in order to form an access to the second connection terminal through the planarization layer. Once the second etch mask has been formed, an inductively coupled plasma dry etching of the planarization layer is carried out, with stopping on the metal of the second connection terminal. Thereafter, the photosensitive resin is removed.

Dry etching allowed the formation of holes through the planarization layer, these holes each having a bottom delimited respectively by the first connection terminals and the second connection terminal. At this stage, for each hole, a metallization layer must be formed covering its bottom, sidewalls of the hole, and a periphery of an opening of the hole arranged at the interface with the face of the planarization layer opposite the substrate.

Such a method has different drawbacks, such as:
the BCB comprises an aromatic core recognized as carcinogenic;
the used BCB necessarily requires an inductively coupled plasma dry etching to access the first connection terminals and the second connection terminal;
the etch of the BCB can be destructive if it is not perfectly adapted to the thickness of BCB to be etched, which is why the opening of the BCB to access the first connection terminals and the second connection terminal must be done in two stages, and, consequently, two photolithographies must be carried out to be adapted to the thickness of BCB to be etched.
   This implies taking into account many parameters and special precautions when manufacturing the electronic device.

### OBJECT OF THE INVENTION

The present invention aims to remedy, at least in part, the aforementioned drawbacks.

To this end, the invention relates to a method for manufacturing an electronic device comprising the following steps:
a) providing a substrate;
b) forming an electronic component from the substrate;
c) forming a planarization layer made of resin on the electronic component, said resin being photosensitive and electrically insulating;
d) carrying out an exposure of the planarization layer through a photolithography mask which results in a delimitation of a sacrificial region within the planarization layer, said sacrificial region being in contact with a part of the electronic component and being able to be removed by a developer;
e) carrying out a development using the developer in order to remove said sacrificial region which results in obtaining a hole having a bottom at least in part delimited by said part of the electronic component;
f) depositing an electrically conductive material to obtain an electrically conductive element at the hole, said electrically conductive element being in contact with the bottom of the hole and with a portion of the planarization layer intended to be permanent within the electronic device, said electrically conductive element having a contact surface arranged on the side of a face of the planarization layer opposite the substrate.

The use of an initially photosensitive resin that remains in place, after its opening (formation of the hole), within the electronic device as a planarization layer makes it possible to advantageously limit the number of steps of the method. Moreover, this makes it possible to use other products than Benzo-Cyclo-Butene, which is currently recognized as a carcinogenic.

The manufacturing method can also comprise one or several of the following characteristics.

According to one characteristic of the manufacturing method, the developer is a product that is inert with respect to the electronic component and preferentially/preferably with respect to the substrate.

This makes it possible to avoid the risk of damage to the electronic device during its manufacture and greatly facilitates the implementation of the manufacturing method in the sense that there are fewer precautions to take than in the case of inductively coupled plasma dry etching.

According to one characteristic of the manufacturing method, the resin comprises a compound derived from the siloxane family, such as cyclopentanone, and the developer is isopropyl alcohol.

The use of isopropyl alcohol is advantageous in the sense that it is a solvent that is inert with respect with respect to the electronic component and to the substrate. The use of such a resin is beneficial because, in addition to its ability to be photosensitive, it has interesting optical characteristics for forming an electronic device of optoelectronic type such as a laser.

According to one characteristic of the manufacturing method, step c) is implemented by a spin coating.

Such a spin coating allows control of the thickness of the planarization layer while ensuring the formation of a flat surface opposite to the substrate.

According to one characteristic of the manufacturing method, step e) is such that the bottom of the hole is connected to an opening of the hole by at least one sidewall protruding from the hole.

This allows high-quality metallization forming the electrically conductive element, thus ensuring suitable electrical conductivity from the electronic component up to the face of the planarization layer opposite the substrate.

According to one characteristic of the manufacturing method, the part of the electronic component delimiting at least in part the bottom of the hole is at least in part delimited by a connection terminal of the electronic component.

The result is that the electrically conductive element allows a contact recovery from the connection terminal up to the face of the planarization layer opposite the substrate.

According to one characteristic of the manufacturing method, the manufacturing method is such that:
step d) is such that the photolithography mask allows the formation of several sacrificial regions within the planarization layer, each of the sacrificial regions being in contact with a corresponding part of the electronic component and being able to be removed by the developer;
step e) is such that the sacrificial regions are all removed at least in part simultaneously, the sacrificial regions being removed so as to form a plurality of holes each having a bottom delimited at least in part by the corresponding part of the electronic component (102);
step f) is such that the deposition of electrically conductive material (M1) is carried out to form electrically conductive elements at each of the holes.

The manufacturing method is thus streamlined because it is possible to use the same development step to form all the holes intended to form connections to the electronic component through the planarization layer.

According to one characteristic of the manufacturing method, the electronic component formed in step b) comprises connection terminals, and each of the corresponding parts of the electronic component is formed at least in part by a surface of one of the connection terminals, at least two of the connection terminals being of different compositions and arranged at different heights relative to the substrate.

The manufacturing method thus makes it possible to combine the steps regardless of the composition of the connection terminals and their height relative to the substrate. This is made notably possible by the use of the photosensitive resin which can be made soluble by the developer only in the locations where it has been exposed (in the case of so-called positive resin) or in the locations where it has not been exposed (in the case of so-called negative resin), and preferentially due to the developer's property of being inert with respect to the electronic component.

According to one characteristic of the manufacturing method, the electronic component is an optoelectronic component, preferably a laser.

This is made notably possible by selecting a photosensitive resin whose optical characteristics are compatible for covering the electronic component.

The invention also relates to an electronic device comprising:
a substrate;
an electronic component formed from the substrate;
a permanent planarization layer derived from a photosensitive resin and arranged in contact with the electronic component;
an electrically conductive element passing through the planarization layer, said electrically conductive element being in contact with a part of the electronic component and having a contact surface arranged on the side of a face of the planarization layer opposite the substrate.

Such an electronic device is advantageous in the sense that its planarization layer can be formed from a material that does not contain a benzene aromatic core. Furthermore, such an electronic device can be obtained at a lower cost in the sense that the photosensitive or polymerized resin remains within the electronic device. Moreover, since the final electronic device does not integrate specific stop layers required in etch techniques to verify that the entire thickness has been etched, it has improved heat dissipation.

The electronic device can comprise several electrically conductive elements each in contact with a corresponding part of the electronic component and each having a contact surface arranged on the side of the face of the planarization layer opposite the substrate.

This makes it possible to allow several distinct contact recoveries for the same electronic component on the side of the face of the planarization layer opposite the substrate.

The electronic device can be such that the electronic component comprises connection terminals and each of the corresponding parts of the electronic component is formed at least in part by a surface of one of the connection terminals, at least two of the connection terminals being of different compositions and arranged at different heights relative to the substrate.

Such an electronic device has an advantage in terms of manufacturing cost in the sense that it results from the presence of the planarization layer made of resin that separate lithography and etch steps are not necessary as well as the presence of specific stop layers to allow access to these connection terminals located under the planarization layer before step e) of the manufacturing method.

Other advantages and characteristics may emerge from the detailed description which follows.

### BRIEF DESCRIPTION OF THE DRAWINGS

The invention will be better understood on reading the following detailed description, given solely by way of non-limiting example and made with reference to the accompanying drawings listed below.

FIG. 1 schematically represents a sectional view of a substrate provided during a method for manufacturing an electronic device according to one embodiment of the invention.

FIG. 2 schematically represents a sectional view showing an electronic component formed on the substrate.

FIG. 3 schematically represents a sectional view showing the deposition of a planarization layer on the electronic component.

FIG. 4 schematically represents a sectional view showing a part of a photolithography step carried out on the assembly shown in FIG. 3.

FIG. 5 schematically shows a sectional view of the result of a development at the end of the photolithography step.

FIG. 6 shows, according to a schematic sectional view, the electronic device at the end of the manufacturing method.

In these figures, the same references are used to designate the same elements. The elements represented in the different figures are not necessarily carried out to scale in order to facilitate understanding of the figures.

### DETAILED DESCRIPTION

In the present description, the frame of reference for the terms “above” or “below” is that of the figures.

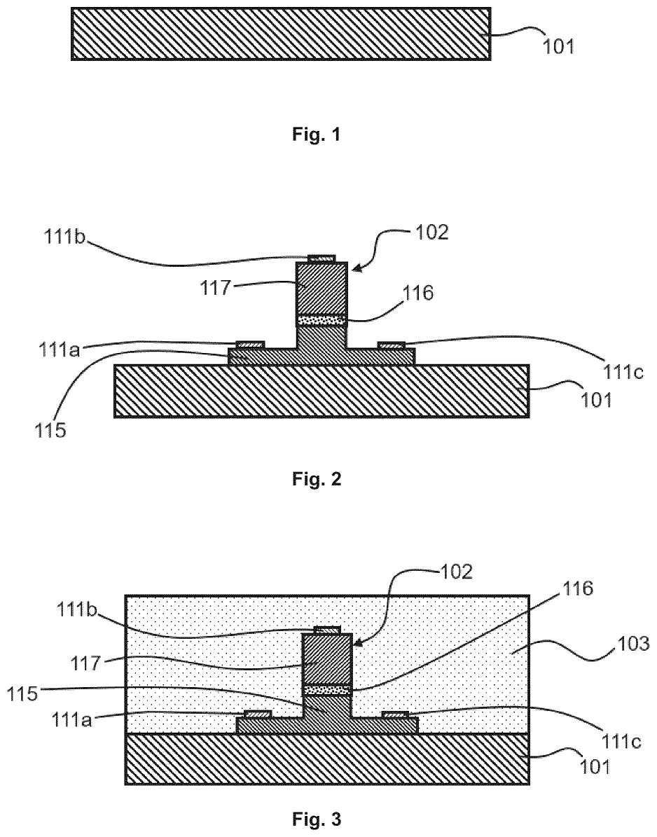

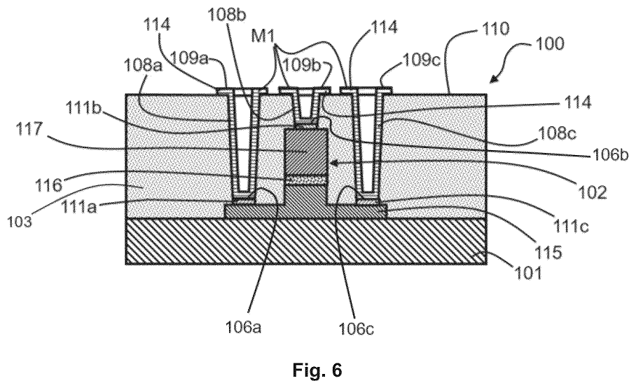

The invention concerns a method for manufacturing an electronic device 100, the various steps of which are illustrated by way of example in FIGS. 1 to 6. The electronic device 100 is notably visible in FIG. 6.

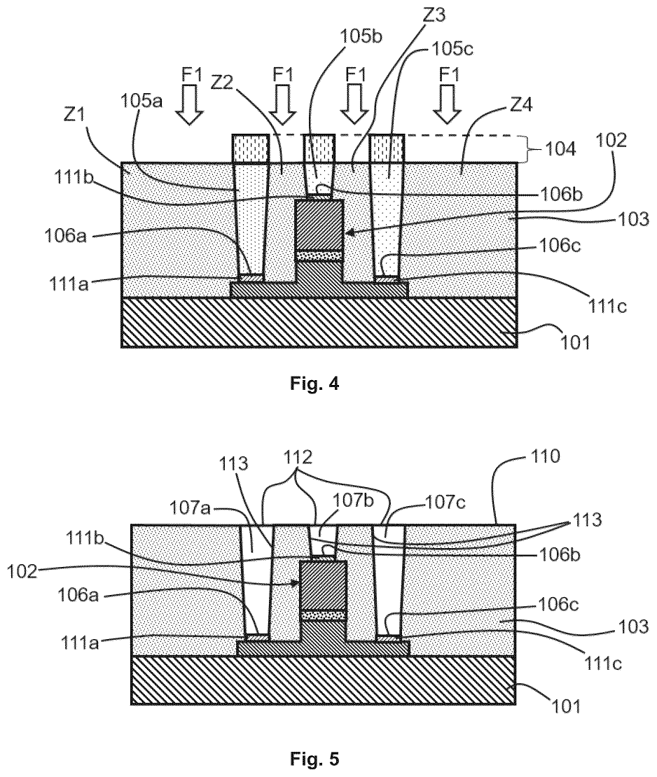

The method for manufacturing the electronic device 100 comprises the following, notably successive, steps:
a) providing a substrate 101 (FIG. 1);
b) forming an electronic component 102 from the substrate 101 (FIG. 2);
c) forming a planarization layer 103 made of resin on the electronic component 102, said resin being photosensitive and electrically insulating (FIG. 3);
d) carrying out an exposure (arrows F1) of the planarization layer 103 through a photolithography mask 104 which results in a delimitation of a sacrificial region 105a, 105b, 105c within the planarization layer 103, said sacrificial region 105a, 105b, 105c being in contact with a part 106a, 106b, 106c of the electronic component 100 and being able to be removed by a developer (FIG. 4);
e) carrying out a development using the developer in order to remove said sacrificial region 105a, 105b, 105c which results in obtaining a hole 107a, 107b, 107c having/comprising a bottom delimited at least in part by said part 106a, 106b, 106c of the electronic component 102 (FIG. 5);
f) depositing an electrically conductive material M1 to obtain an electrically conductive element 108a, 108b, 108c at the hole 107a, 107b, 107c, said electrically conductive element 108a, 108b, 108c being in contact with the bottom of the hole 107a, 107b, 107c and notably with a portion of the planarization layer 103 intended to be permanent within the electronic device 100, said electrically conductive element 108a, 108b, 108c having/comprising a contact surface 109a, 109b, 109c arranged on the side of a face 110 of the planarization layer 103 opposite the substrate 101 (FIG. 6).

Steps c), d) and e) together form a photolithography step.

Step d) can be implemented using radiation, notably “electromagnetic radiation”, of a predetermined wavelength, for example using a mercury lamp, adapted help delimit the sacrificial region 105a, 105b, 105c due to the insolation of the planarization layer 103 through the photolithography mask 104 by said radiation.

Step f) allows notably to form, at the hole 107a, 107b, 107c, an interconnection hole also called via or metallized hole in the field.

In particular, the contact surface 109a, 109b, 109c, arranged on the side of the face 110 of the planarization layer 103 opposite the substrate 101, is resulting from a portion of the layer deposited in material M1, this portion being deposited on said face 110.

It results from the transition from FIG. 4 to FIG. 5 that the resin used to form the planarization layer 103 is a so-called negative resin in the sense that each area exposed to radiation resists development, that is to say that the sacrificial region 105a, 105b, 105c is unpolymerized and soluble in the developer (it is for example in this sense that areas Z1, Z2, Z3, Z4 of the planarization layer 103, insoluble in the developer, whose pattern has locally changed between FIG. 3 and FIG. 4 are identifiable in FIG. 4). Of course, this is not limiting in the sense that the resin can just as well be a positive resin: in this case the photolithography mask 104 will be adapted and will not cover each area to be opened, i.e. corresponding to the sacrificial region 105a, 105b, 105c which is then a polymerized portion of the resin used to form the planarization layer 103.

Notably, the photolithography mask 104 is only used for exposure and is not permanent on the surface of the planarization layer 103.

One advantage of using the planarization layer 103 made of photosensitive resin is that it avoids implementing a step of etching a planarizing layer, which requires providing an etch mask formed, for example, by photolithography on the planarizing layer to be etched, with a specific etch stop to be provided. Furthermore, it allows the use of materials other than Benzo-Cyclo-Butene recognized as carcinogenic.

Depending on the type of electronic device 100, the substrate 100 can be a silicon substrate or a substrate made of III-V material, i.e. a material composed of one or several elements from column III and column V of Mendeleev's periodic table.

By “electronic component 102” formed from the substrate 101, it is understood that the “electronic component 102” can be formed on the substrate 101, which then forms a simple support, or be partly integrated into the substrate 101, a part of which also forms a portion of the electronic component 102.

Step c) is notably carried out so that the planarization layer 103 covers the electronic component 102 which is then located under the face 110 of the planarization layer 103 opposite the substrate.

Thus, the invention also relates to the electronic device 100, notably as obtained by the manufacturing method, and for example visible in FIG. 6. The electronic device 100 comprises:
the substrate 101;
the electronic component 102 formed from the substrate 101, and notably arranged on the substrate 101;
the planarization layer 103 then permanent (i.e. which remains within the electronic device 100 notably throughout its use) derived from the photosensitive resin and arranged in contact with (i.e. arranged on) the electronic component 102;
an electrically conductive element 108a, 108b, 108c passing through the planarization layer 103, said electrically conductive element 108a, 108b, 108c being in contact with a part 106a, 106b, 106c of the electronic component 102 and having/comprising a contact surface 109a, 109b, 109c (notably turned towards a direction opposite the substrate 101) arranged on the side of the face 110 of the planarization layer 103 opposite the substrate 101.

By “the permanent planarization layer 103 derived from a photosensitive resin” it is understood that the planarization layer 103 can be made, within the electronic device 100, of photosensitive resin (when the resin is positive) or exposed resin that is no longer photosensitive (when the resin within the electronic device 100 is made of negative exposed resin—also called polymerized resin—during the manufacturing method and is therefore no longer photosensitive). The result is that the electronic device 100 is notably the one obtained during the manufacturing method.

The substrate 101 can be a plate for the formation of electronic components also called a “wafer” in the technical field of the invention (this may notably be the case in the context of the manufacturing method) or a cut portion of the plate in the context of the electronic device 100 for example integrated into an electronic chip.

It results from what has been described above that the planarization layer 103, following step e) (and therefore what remains of it after development), is permanent in the sense that it is always present in the electronic device 100, although modified compared to its state at the end of step c), notably during steps d) and e). Thus, the portion of the planarization layer 103 intended to be permanent within the electronic device 100 is part of the planarization layer 103 in its “permanent” state after step e).

Preferably, in order to avoid damaging the electronic component 102 during carrying out step e), the developer is a product that is inert with respect to the electronic component 102. Using such an inert product makes it possible to eliminate the need for rigorous control, as is the case with an etch step, which could damage the electronic component 102. In the case where the planarization layer 103 protects the substrate 101 during step e) (case where the corresponding sacrificial region 105a, 105b, 105c is not in contact with the substrate 101 but only with the electronic component 102), it can be sufficient for the developer to be a product that is inert with respect to the electronic component 102. Preferably, the developer is a product that is also inert with respect to the substrate 101, this allows to avoid damage to the substrate 101 if the developer comes into contact with the latter, notably when the corresponding sacrificial region 105a, 105b, 105c is in contact with the electronic component 102 and the substrate 101.

The resin can comprise a compound derived from the siloxane family, such as cyclopentanone, and the developer can be isopropyl alcohol.

For example, the resin can be SINR from the manufacturer ShinEtsu. Such a resin is a negative resin.

In the case of SINR, step d) can be implemented using ultraviolet radiation, and before step e) annealing of the planarization layer 103 can be carried out.

Alternatively, the resin can comprise HSQ (abbreviation for hydrogen silsesquioxane) and be a negative resin sensitive to extreme ultraviolet radiation. In this case, the developer can be based on TMAH (abbreviation of tetramethylammonium hydroxide).

The resin can also be SIPR, also produced by the manufacturer ShinEtsu, which is a positive resin which develops however in TMAH which is a base and not a solvent; this then amounts to making an etching of a resin which does not contain BCB, which is better for health reasons but which is not inert for the electronic component 102 and the substrate 101.

A major advantage of SINR is that its developer is isopropyl alcohol, which is inert to the surfaces encountered in microelectronics, unlike TMAH which can etch certain materials.

In general, and in order to obtain a flat surface opposite to the substrate 101, step c) can be implemented by spin coating. This makes it possible to avoid the need for a chemical-mechanical polishing method which generally increases production costs because it involves the implementation of an additional step.

Preferably, step e) is such that the bottom of the hole 107a, 107b, 107c is connected to an opening 112 of the hole 107a, 107b, 107c (notably arranged at the face 110 of the planarization layer 103) by at least one sidewall 113 protruding from the hole (FIG. 5), and preferably by protruding sidewalls. This makes it possible to facilitate the deposition of the electrically conductive material M1 onto the sidewall(s)/wall(s) of the hole 107a, 107b, 107c in order to form a high-quality interconnection hole.

By protruding sidewall(s), it is understood that the concerned sidewall diverges from the bottom of the hole 107a, 107b, 107c with respect to an axis of the hole 107a, 107b, 107c orthogonal to the plane of the substrate 101. A protruding sidewall is also called a sidewall with a positive slope.

For the same hole 107a, 107b, 107c, the latter can comprise a sidewall with a circular cross-section increasing as one moves away from the substrate 101 or several sidewalls intersecting two by two, each extending from the bottom of the hole 107a, 107b, 107c.

Notably, the presence of the protruding sidewall(s) is a consequence of an adapted photolithography (notably steps d) and e)) which allows to obtain naturally (notably in the case of SINR), or by appropriately controlling the insolation, a shape adapted for the continuous deposition of a layer carried out in the electrically conductive material M1 between the bottom 107a, 107b, 107c of the hole and the periphery of its opening 112 on the side of the face 110 of the planarization layer 103 opposite to the substrate 101. This makes it possible to limit the scrap rate linked to a problem of electrical conduction at the contact recovery ensured by the electrically conductive element 108a, 108b, 108c.

The electrically conductive element 108a, 108b, 108c is notably such that it comprises a collar 114 arranged on the face 110 of the planarization layer 103 opposite, and notably distal to, the substrate 101. Although this is not preferred, the electrically conductive element 108a, 108b, 108c can fill the corresponding hole 107a, 107b, 107c.

Preferably, the part 106a 106b, 106c of the electronic component 102 delimiting at least in part the bottom of the hole 107a, 107b, 107c is at least in part delimited by a connection terminal 111a, 111b, 111c of the electronic component 102.

As shown for example in FIG. 5, the part 106a 106b, 106c of the electronic component 102 delimits the bottom of the hole 107a, 107b, 107c and is delimited by the connection terminal 111a, 111b, 111c of the electronic component 102.

This connection terminal 111a, 111b, 111c can be made of metal. For example, in the case where the electronic component 102 is a laser, the connection terminal can comprise or be made up of a stack of three layers comprising successively, from a corresponding part of the electronic component 102, a nickel layer, a germanium layer and a gold layer, or comprising successively, from a corresponding part of the electronic component 102, a titanium layer, a platinum layer and a gold layer.

The connection terminal 111a, 111b, 111c is not mandatory if the electrically conductive element 108a, 108b, 108c can be deposited directly in contact with a layer within the electronic component 102 while still allowing it to perform its function, notably contact recovery.

Everything that applies to the electrically conductive element 108a, 108b, 108c and to the hole 107a, 107b, 107c can apply to each of several electrically conductive elements 108a, 108b, 108c and several holes 107a, 107b, 107c as described below.

Thus, the electronic component 102 can comprise several electrically conductive elements 108a, 108b, 108c as described (for example, three as illustrated in FIG. 6) in order to enable contact recovery on the electronic component 102. To this end, and to enable combining the formation of these electrically conductive elements 108a, 108b, 108c, step d) can be such that the photolithography mask 104 allows the formation of several sacrificial regions 105a, 105b, 105c (each as described above) within the planarization layer 103. Notably, there are as many sacrificial regions 105a, 105b, 105c as there are electrically conductive elements 108a, 108b, 108c. Therefore, each of the sacrificial regions 105a, 105b, 105c is in contact with a corresponding part 106a, 106b, 106c of the electronic component 102 and is able to be removed by the developer. Thus, step e) is such that the sacrificial regions 105a, 105b, 105c are all removed at least in part simultaneously (this depends, of course, on the morphology of the sacrificial regions relative to each other, as the removal of one may be completed before the removal of another). In fact, the sacrificial regions 105a, 105b, 105c are removed so as to form a plurality of holes 107a, 107b, 107c (three in the example illustrated in FIG. 5), each having/comprising a bottom delimited at least in part by the corresponding part 106a, 106b, 106c of the electronic component 102, and preferably delimited by the corresponding part 106a, 106b, 106c of the electronic component 102, which can be a connection terminal 111a, 111b, 111c of the latter as described above. Step f) is such that the deposition of the electrically conductive material M1 allows the formation of the electrically conductive elements 108a, 108b, 108c at each of the holes 107a, 107b, 107c.

The use of the photosensitive resin to form the planarization layer 103 which will be opened locally by the developer, (for example by plunging the assembly visible in FIG. 4, after removal of the photolithography mask 104, into a liquid forming the developer) in order to then deposit the electrically conductive material M1 on the planarization layer 103 after step e), allows simultaneous opening in different locations on the face 110 of the planarization layer 103 and, where appropriate, at different depths in a way that is simple to industrialize.

The electrically conductive elements 108a, 108b, 108c are notably electrically isolated from each other either at the end of step f) in the case of localized deposition, or by etching the deposited electrically conductive material M1.

In general, the electrically conductive material M1 can be a metal, for example selected from gold and aluminum.

Thus, the electronic device 100 can comprise several electrically conductive elements 108a, 108b, 108c, each as described and in contact with a corresponding part 106a, 106b, 106c of the electronic component 102 and each having/comprising a contact surface 109a, 109b, 109c arranged on the side of the face 110 of the planarization layer 103 opposite the substrate 101. Thanks to this, it is possible to form electrical links connecting the electronic component 102 through the planarization layer 103, for example to connect an additional electronic component to the electronic component 102 comprising the planarization layer 103, for example by the (“flip-chip”) transfer technique.

It is understood from the foregoing that the electrically conductive elements 108a, 108b, 108c can be electrically connected, notably by direct contact to the connection terminals 111a, 111b, 111c of the electronic component 102, notably in an individualized way. To this end, the electronic component 102 formed in step b) comprises the connection terminals 111a, 111b, 111c, for example three, and each of the corresponding parts 106a, 106b, 106c of the electronic component 102 is formed at least in part (and preferably entirely) by a surface of one of the connection terminals 111a, 111b, 111c.

Preferably, at least two of the connection terminals 111a, 111b, 111c are of different compositions and/or arranged at different heights relative to the substrate 101. Here it is then understood an advantage to use the resin within the planarization layer 103: it can be opened simply and simultaneously without worrying about etch time or etch stop selectivity.

By “different compositions”, it is understood, for example, that said at least two connection terminals of different compositions each comprise at least one material different from one material of the other of said at least two connection terminals of different compositions. For example, two stacks of three layers have been described above, these two stacks of three layers are of different compositions and can each be selected to form one of said at least two of the connection terminals 111a, 111b, 111c of different compositions.

Thus, within the framework of the electronic device 100, the electronic component 102 can comprise the connection terminals 111a, 111b, 111c and each of the corresponding parts 106a, 106b, 106c of the electronic component 102 is formed at least in part by a surface of one of the connection terminals 111a, 111b, 111c, at least two of the connection terminals 111a, 111b, 111c being of different compositions and/or arranged at different heights relative to the substrate 101.

According to a preferred embodiment, the electronic component 102 is an optoelectronic component, preferably a laser. A resin is particularly suitable for forming a planarization and encapsulation layer 103 of an optoelectronic component. Indeed, due to its photosensitivity, it is optically suited so as not to impede the operation of the optoelectronic component.

A particular example of carrying out a laser as an electronic component 102 is now described. In this particular example, the substrate 101 can be made of silicon or a III-V material; it then serves as a support for the electronic component 102, which comprises (FIG. 2):
a N-doped InP base 115 arranged on the substrate 101;
a quantum layer 116, also called the active area, intended to form a Fabry-Pérot cavity of the laser and arranged on the base 115 notably on a vertex of a body of the base 115 extending from a foot of the base;
a P-doped InP layer 117 formed on the quantum layer 116 forming a ribbon so-called “III-V ribbon”.
   The electronic component 102 comprises two connection terminals 111a, 111c, each comprising a successive stack of a nickel layer, a germanium layer, and a gold layer formed on the base 115 such that the nickel layer is in contact with the base 115 (notably on both sides of its body), forming metallic contacts at the substrate 101. The electronic component 102 further comprises a connection terminal 111b comprising a successive stack of a titanium layer, a platinum layer, and a gold layer at the vertex of the P-doped InP layer opposite to the substrate 101, forming a ribbon contact (the titanium layer then being in contact with said vertex). The result is that, apart from the possible use of different compositions to form the connection terminals 111a, 111c and the connection terminal 111b, the connection terminals 111a, 111c and the connection terminal 111b are not at the same level above the substrate 101.

The described manufacturing method is particularly well-suited to such a laser, in the sense that the photosensitive planarization layer 103 can be opened simultaneously at different topographic levels. SINR is preferentially used here as the photosensitive resin because it has compatible optical characteristics for covering the laser. The planarization layer 103 enables contact recovery at the same level and, where appropriate, enables electrical connection of the electronic device to an electronic chip by a transfer technique.

Of course, the invention is not limited to a laser as an electronic component 102, any other type of electronic component, for example light-emitting diodes, having notably a strong topography requiring planarization with contact recovery can be used within the framework of the present invention.

The present invention finds industrial application in the field of manufacturing electronic components, notably in the field of microelectronics.

1. A method for manufacturing an electronic device comprising the following steps:
a) providing a substrate;
b) forming an electronic component from the substrate
c) forming a planarization layer made of resin on the electronic component, said resin being photosensitive and electrically insulating;
d) carrying out an exposure of the planarization layer through a photolithography mask which results in a delimitation of a sacrificial region within the planarization layer, said sacrificial region being in contact with a part of the electronic component and being able to be removed by a developer;
e) carrying out a development using the developer in order to remove said sacrificial region which results in obtaining a hole having a bottom delimited at least in part by said part of the electronic component;
f) depositing an electrically conductive material (M1) to obtain an electrically conductive element at the hole said electrically conductive element being in contact with the bottom of the hole and with a portion of the planarization layer intended to be permanent within the electronic device, said electrically conductive element having a contact surface arranged on the side of a face of the planarization layer opposite the substrate;
and wherein:
step d) is such that the photolithography mask allows the formation of several sacrificial regions within the planarization layer each of the sacrificial regions being in contact with a corresponding part of the electronic component and being able to be removed by the developer;
step e) is such that the sacrificial regions are all removed at least in part simultaneously, the sacrificial regions being removed so as to form a plurality of holes each having a bottom delimited at least in part by the corresponding part of the electronic component;
step f) is such that the deposit of electrically conductive material (M1) is carried out to form electrically conductive elements at each of the holes;
wherein the electronic component formed in step b) comprises connection terminals and wherein each of the corresponding parts of the electronic component is formed at least in part by a surface of one of the connection terminals, at least two of the connection terminals being arranged at different heights relative to the substrate.

2. The manufacturing method according to claim 1, wherein the developer is a product that is inert with respect to the electronic component and preferentially with respect to the substrate.

3. The manufacturing method according to claim 1, wherein the resin comprises a compound derived from the siloxane family, such as, for example, a cyclopentanone, and wherein the developer is isopropyl alcohol.

4. The manufacturing method according to claim 1, wherein step c) is implemented by a spin coating.

5. The manufacturing method according to claim 1, wherein step e) is such that the bottom of each hole is connected to an opening of said hole by at least one sidewall protruding from said hole.

6. The manufacturing method according to claim 1, wherein said at least two of the connection terminals are of different compositions.

7. The manufacturing method according to claim 1, wherein the electronic component is an optoelectronic component, preferably a laser.

8. An electronic device comprising:
a substrate;
an electronic component formed from the substrate;
a permanent planarization layer derived from a photosensitive resin and arranged in contact with the electronic component;
several electrically conductive elements passing through the planarization layer, each in contact with a corresponding part of the electronic component and each having a contact surface arranged on the side of a face of the planarization layer opposite the substrate;
wherein the electronic component comprises connection terminals and wherein each of the corresponding parts of the electronic component is formed at least in part by a surface of one of the connection terminals, at least two of the connection terminals being arranged at different heights relative to the substrate.

9. The electronic device according to claim 8, wherein said at least two of the connection terminals are of different compositions.
